(19) United States
(12) Patent Application Publication
(10) Pub. No.: US 2016/0369393 A1
(43) Pub. Date: Dec. 22, 2016

(54) POLYCRYSTALLINE GERMANIUM-ALLOYED SILICON AND A METHOD FOR THE PRODUCTION THEREOF

(71) Applicant: Wacker Chemie AG, Muenchen (DE)

(72) Inventors: Laszlo FABRY, Burghausen (DE); Mikhail SOFIN, Burghausen (DE)

(21) Appl. No.: 15/256,855

(22) Filed: Sep. 6, 2016

Related U.S. Application Data
(62) Division of application No. 12/630,001, filed on Dec. 3, 2009, now abandoned.

(30) Foreign Application Priority Data
Dec. 11, 2008 (DE) 10 2008 054 519.8

(51) Int. Cl. C23C 16/22; C23C 16/02

(52) U.S. Cl. CPC C23C 16/22; C23C 16/0209; C30B 29/52

(57) ABSTRACT

A rod having a length of 0.5 m to 4 m and having a diameter of 25 mm to 220 mm, comprising a high-purity alloy composed of 0.1 to 50 mol % germanium and 99.9 to 50 mol % silicon, the alloy having been deposited on a thin silicon rod or on a thin germanium-alloyed silicon rod, the deposited alloy having a polycrystalline structure.

### CROSS-REFERENCE TO RELATED APPLICATIONS

This application is a Divisional of and claims priority to U.S. Ser. No. 12/630,001, filed Dec. 3, 2009, now pending, and also claims priority to German Patent Application No. DE 10 2008 054 519.8, filed Dec. 11, 2008, the disclosures of which are incorporated in their entirety by reference herein.

### BACKGROUND OF THE INVENTION

1. Field of the Invention

The invention relates to polycrystalline germanium-alloyed silicon and a method for the production thereof.

2. Background Art

Germanium-alloyed silicon has advantages over polycrystalline silicon in a variety of applications. Thus, a band gap of between 1.7-1.1 eV can be set with germanium alloys of semiconductor silicon. This makes it possible to increase the efficiency of SiGe stacked cells in solar modules, for example, if the lower cell has a band gap of around approximately 1.2-1.4 eV and the topmost cell has a band gap of approximately 1.7 eV. For solar silicon, in particular, there is therefore a need for germanium-alloyed silicon. It is furthermore known from the abstract of JP5074783A2 (Fujitsu) that the gettering of metallic impurities is more effective in germanium-alloyed silicon crystals than in pure Si crystals. It is assumed that germanium can advantageously influence defect formation. The charge carrier mobility is also higher in strained SSi structures (SSi: strained silicon) than in pure monocrystalline silicon.

Hitherto, SSi layers on relaxed SiGe wafer layers have been produced with additional outlay by the doping of germanium crystals in crystal pulling installations (see e.g. EP1777753) or by the deposition of germanium-containing gases on pure silicon in an epitaxy reactor (see e.g. US2005/0012088).

### SUMMARY OF THE INVENTION

It is an object of the present invention to provide a high-purity polycrystalline germanium-alloyed silicon rod and also a simple and cost-effective method for the production thereof. These and other objects are achieved by means of a rod having a length of 0.5 m to 4 m and having a diameter of 25 mm to 220 mm, comprising a high-purity alloy composed of 0.1 to 50 mol % germanium and 99.9 to 50 mol % silicon, this alloy having been deposited on a thin silicon rod or on a thin germanium-alloyed silicon rod, the deposited alloy having a polycrystalline structure.

### DETAILED DESCRIPTION OF THE PREFERRED EMBODIMENT(S)

For the purposes of the present invention, high-purity should be understood to mean that the germanium-alloyed silicon rod contains a maximum of 1 ppma of dopants, 0.3 ppma carbon and a maximum of 0.1 ppma of metals other than of germanium. In this case, dopants are preferably understood to mean shallow donors such as P, As, Sb and/or shallow acceptors such as B, Al, Ga, In.

In the rod, the donor density (e.g. the amount of P, As, Sb) is preferably less than 3 ppma, more preferably less than 1 ppba, and most preferably less than 0.3 ppba, and the acceptor density (e.g. the amount of B, Al, Ga, In) is less than 3 ppma, more preferably less than 1 ppma, yet more preferably less than 0.3 ppma, and most preferably less than 0.1 ppba. Such a material is particularly suitable for photovoltaic solar applications.

Most solar cells are produced from boron-doped p-type silicon. If the polycrystalline rod according to the invention has to be overcompensated therefor, the donor density is preferably less than 1 ppma, preferably less than 0.3 ppma, in order to be able to set the specified net acceptor density of 100-300 ppba with low boron doping.

The impurity of metals with the exception of germanium is preferably not more than 1 ppba.

For the purposes of the present invention, a polycrystalline structure should be understood to mean that the rod comprises single crystals separated from one another by grain boundaries, the single crystals having an average grain size of between 0.1 and 100 micrometers.

The germanium-alloyed silicon rod according to the invention can be used for FZ (float zone) crystal pulling or for recharging in the Czochralski method. Methods of this type are carried out analogously to the production of single crystals composed of silicon, such as are described for example in SEMICONDUCTOR SILICON CRYSTAL TECHNOLOGY by F. Shimura (Academic Press, London 1988, pages 124-127, 130-131, 135 and 179).

The germanium-alloyed silicon rod of the invention can be comminuted into fragments by known methods. Methods of this type are described in US2006/0088970A1 or US2007/0235574A1, for example. The fragments can be used as a starting material for the production of relaxed SSi and/or for block-cast multicrystalline products without additional germanium doping which has been required heretofore.

A germanium-alloyed silicon rod according to the invention can be produced by a method in which a starting gas is introduced into a Siemens reactor and brought into contact there with a glowing thin rod, deposition from the starting gas occurring on the thin rod, wherein the thin rod comprises silicon or germanium-alloyed silicon and the starting gas comprises hydrogen, at least one silicon-containing compound and at least one germanium-containing compound.

For the commercial production of polycrystalline ultrapure silicon by means of Siemens technology, two method variants are used, which differ primarily in the composition of the starting gas. In the case of the first, chlorine-free, method variant, a mixture of monosilane and hydrogen is conducted into a Siemens reactor and brought into contact there with an electrically heated glowing silicon rod. In the case of the second method variant, which is employed more frequently, the starting gas comprises hydrogen and trichlorosilane and/or dichlorosilane, and it is in turn introduced into the Siemens reactor with electrically heated glowing silicon rods (thin rods). These two conventional methods for producing polycrystalline silicon are converted into methods according to the invention by the addition of gaseous germanium-containing compounds. The method according to the invention thus makes it possible to produce polycrystalline germanium-alloyed silicon in conventional Siemens reactors such as are used for the production of polycrystalline ultrapure silicon. The thin rods comprise silicon or germanium-alloyed silicon.

In the chlorine-free variant of the method according to the invention, the rod is produced by means of a method in which a starting gas comprising hydrogen and a mixture of monogermane and monosilane or disilane is brought into contact with glowing rods composed of silicon or germanium-alloyed silicon in a Siemens reactor, the deposition of a polycrystalline alloy composed of germanium and silicon occurring on the rod.

The composition and the morphology of the deposited material can be set by varying the ratio of the monogermane to monosilane or monogermane or disilane in the starting gas and the temperature of the thin rod or of the substrate on which the deposition is effected.

If a monogermane/disilane mixture is used in the starting gas, then the molar germanium fraction in the deposited polycrystalline alloy composed of germanium and silicon corresponds approximately to the molar germanium-to-silicon ratio in the starting gas, since monogermane and disilane have approximately the same thermal stability. A monogermane/disilane mixture in the starting gas thus enables simple regulation of the alloy composition of the rod according to the invention by means of corresponding regulation of the monogermane/disilane ratio in the starting gas. It is preferred, therefore, to use monogermane in the monogermane/disilane mixture in a ratio which corresponds to the desired germanium fraction in the polycrystalline germanium-alloyed silicon rod. In general, in this method variant, GeH₄ to Si₂H₆ in a molar ratio of 0.1:49.95 (for alloys comprising approximately 0.1 mol % Ge) to 2:1 (for alloys comprising approximately 50 mol % Ge) is used in the starting gas.

In this method variant, deposition is preferably effected at a temperature of 300° C. to 800° C. and a starting gas saturation (molar fraction of the Ge- and Si-containing compounds in the H2-based mixture) of 0.5-20 mol %.

The amount of gas added depends on the temperature and the available substrate area, that is to say on the number, length and current diameter of the rods in the Siemens reactor. It is advantageous to choose the amounts of starting gas added such that the deposition rate of the silicon/germanium alloy is 0.1 to 1.5 mm per hour. Through a suitable combination of the process parameters such as gas flow rate, starting gas saturation and substrate temperature, it is possible to set process and product features such as conversion, deposition rate, morphology of the deposited alloy and proportion of homogeneously deposited silicon. Preferably, the deposition is intended to be carried out at a starting gas saturation of 0.5-5 mol %, a substrate temperature of 350-600° C. and a gas flow rate (GeH₄+½ Si₂H₆) of 10-150 mol per 1 m² substrate surface.

In the method variant in which the polycrystalline germanium-alloyed silicon rod is deposited in the Siemens reactor using a monogermane/monosilane mixture in the starting gas, preferably monogermane is converted from the gas mixture. This method variant is less suitable for the production of a polycrystalline germanium-alloyed silicon rod having a high germanium content, for economic reasons. However, this method variant affords advantages if a polycrystalline germanium-alloyed silicon rod having a low germanium content, which should preferably be understood to mean a germanium content <20 mol %, is intended to be produced. In the case of a germanium content of less than 20 mol % in the monogermane/monosilane mixture, monogermane is completely converted and the exhaust gas flowing out of the reactor is accordingly free of germanium. This simplifies the treatment of the exhaust gas and makes it possible for the latter to be used further without an additional separation method in the combined system which is almost always used in the commercial production of ultrapure silicon (see U.S. Pat. No. 4,826,668, for example). Preferably, a mixture of monogermane to monosilane in a molar ratio of 0.1:99.9 to 50:50 is therefore used in this method variant.

In this method variant, the deposition conditions preferably correspond to those which are used in the production of ultrapure silicon from SiH₄: the substrate temperature preferably lies between 400° C. and 1000° C. and the starting gas saturation preferably lies between 0.1 mol % and 10 mol %. It is advantageous to choose the amounts of starting gas such that the SiGe deposition rate is 0.1 to 1.5 mm per hour. This deposition rate is established at the specified temperature and saturation if the throughput of GeH₄ and SiH₄ is in total between 10 and 150 mol per m² substrate area.

In the invention, in the second variant, in addition to dichlorosilane and/or trichlorosilane, germanium tetrachloride or trichlorogermane is also introduced into the Siemens reactor. In this case, germanium tetrachloride is most suitable for the deposition of SiGe polycrystals and is thus preferably used.

The deposition of SiGe polycrystals composed of dichlorosilane, trichlorosilane and germanium tetrachloride affords advantages, since firstly, the thermal stability of these compounds is approximately identical and, secondly, the exhaust gas only contains one additional Ge-containing compound, namely unconverted germanium tetrachloride.

The deposition in this variant is preferably effected at a substrate temperature of between 700° C. and 1200° C. and is preferably carried out at a saturation of the starting gas of said gas mixture of 5 to 50 mol %. It is advantageous to choose the amounts of starting gas added such that the SiGe deposition rate is 0.1 to 1.5 mm per hour. This deposition rate is established at the specified temperature and saturation if the throughput of dichlorosilane, trichlorosilane and germanium tetrachloride is in total between 50 and 5000 mol per m² substrate area.

Both variants of the method according to the invention can be used for the production of a polycrystalline germanium-alloyed silicon rod with semiconductor quality and with solar quality.

In this case, semiconductor quality should preferably be understood to mean that 99.9999999% by weight (9 N) of germanium-alloyed Si (GeₓSi₁₋ₓ, 0.001<x<0.5) contains shallow donors, max. 0.3 ppba; shallow acceptors max. 0.1 ppba; carbon max. 0.3 ppma; and alkali, alkaline earth, transition and heavy metals (with the exception of germanium) max. 1 ppba.

In this case, solar quality should preferably be understood to mean that 99.9999% by weight (6 N) of germanium-alloyed Si (GeₓSi₁₋ₓ, 0.001<x<0.5) contains shallow donors max. 1 ppma; shallow acceptors max. 1 ppma; carbon max. 2 ppma; and alkali, alkaline earth, transition and heavy metals (with the exception of germanium) max. 500 ppba.

Rods having one of the abovementioned compositions are particularly preferred embodiments of the rods according to the invention.

The examples below serve to elucidate the invention further. All the examples were carried out in a Siemens reactor with 8 thin rods. The thin rods used for the deposition comprised ultrapure silicon, had a length of 1 m and had a square cross section of 5×5 mm. Since the proportion of the thin rod in the thick deposited rod is very small (<0.5%), the influence thereof on the entire composition of the rod after deposition is negligibly small. In all the examples, the gas flow rate was controlled such that the deposition rate was in the optimum range of 0.1 to 1.5 mm/h. When using reactors having a different number or length of the thin rods, it is necessary to correspondingly adapt the gas flow rate if the same deposition rate is desired. The same holds true if other substrates (e.g. tubes or polygons) or temperatures are used. In the examples below, the amount of gas added was regulated depending on the growth rate. The growth rate was controlled by means of the rod diameter increase. Alternatively, the deposition rate can be calculated on the basis of the composition of the exhaust gas flowing out of the reactor.

### Example 1

GeH₄ and Si₂H₆ were used as starting compounds. Together with hydrogen (molar proportions: GeH₄ 1.0%, Si₂H₆ 4.5%, remainder H₂), the starting compounds were introduced by nozzles into the Siemens reactor. The temperature of the rods was 500° C. during the entire deposition time. After 250 hours, the deposition process (which proceeded with the constant growth rate) ended. The average rod diameter was 132 mm. The molar Ge content in the polycrystalline SiGe rods was 9.5%.

### Example 2

GeH₄ and SiH₄ were used as starting compounds. Together with hydrogen (molar proportions: GeH₄ 0.5%, SiH₄ 4.5%, remainder H2), the starting compounds were introduced by nozzles into the Siemens reactor. The deposition was carried out with a constant growth rate and lasted 200 hours at a rod temperature of 700° C. In this case, the rods attained a diameter of approximately 135 mm and had a Ge content of 18 mol %.

### Example 3

Dichlorosilane and germanium tetrachloride were used as starting compounds. Together with hydrogen (molar proportions: dichlorosilane 5%, germanium tetrachloride 5%, remainder H₂), the starting compounds were introduced by nozzles into the Siemens reactor. The deposition was carried out at a rod temperature of 1000° C. with a constant growth rate and lasted 200 hours. The gas flow rate was regulated such that the deposition rate was approximately 0.3 mm/h. The deposition ended after 220 hours. The rods were approximately 137 mm thick and had a Ge content of approximately 49 mol %.

### Example 4

The gas mixture used during the deposition comprised 1 mol % germanium tetrachloride, 4 mol % dichlorosilane and 15 mol % tetrachlorosilane and hydrogen. The rod temperature was 1050° C. The gas flow rate was regulated such that the deposition rate was 0.45 mm/h. The deposition ended after 170 hours. The deposited rods had a diameter of 159 mm and contained approximately 7 mol % Ge.

While embodiments of the invention have been illustrated and described, it is not intended that these embodiments illustrate and describe all possible forms of the invention. Rather, the words used in the specification are words of description rather than limitation, and it is understood that various changes may be made without departing from the spirit and scope of the invention.

What is claimed is:

1. A method for producing a silicon/germanium alloy product rod comprising a thin rod of silicon or germanium-alloyed silicon and a deposited layer of a polycrystalline alloy of silicon and germanium, deposited by chemical vapor deposition in a Siemens reactor, the method comprising:
supplying at least one thin rod of silicon or germanium-alloyed silicon in a Siemens reactor;
heating the thin rod to a temperature of between 400° C. and 1000° C.;
introducing a deposition gas mixture comprising hydrogen and a mixture of monogermane and monosilane having a germanium fraction of less than 20 mol % into the Siemens reactor; and
depositing a polycrystalline silicon/germanium alloy onto the thin rod, increasing the diameter of the thin rod to a diameter of from 25 mm to 220 mm,
wherein the silicon/germanium alloy deposited comprises 0.1 to less than 20 mol % germanium, and 99.9 to 80 mol percent silicon, and wherein the silicon/germanium product rod has a length of from 0.5 m to 4 m.

2. The method of claim 1, wherein the deposition gas mixture has a starting gas saturation of 0.1 mol % to 10 mol % and a throughput of monogermane and monosilane is between 10 and 150 mol per m² of rod surface area, such that the polycrystalline silicon/germanium alloy is deposited at a rate of 0.1 to 1.5 mm per hour.

3. The method of claim 1, wherein the silicon/germanium product rod contains a maximum of 1 ppma of dopants, 0.3 ppma of carbon, and 0.1 ppma of metals other than germanium.

4. The method of claim 1, wherein the silicon/germanium product rod contains less than 3 ppma of donor dopants.

5. The method of claim 1, wherein the silicon/germanium product rod contains less than 3 ppma of acceptor dopants.

6. The method of claim 1, wherein the silicon/germanium product rod contains less than 1 ppma of donor dopants.

7. The method of claim 1, wherein the thin rod comprises <0.5 wt. % of the silicon/germanium product rod.
